(19) United States
(12) Patent Application Publication
(10) Pub. No.: US 2025/0244754 A1
(43) Pub. Date: Jul. 31, 2025

(54) INFORMATION PROCESSING METHOD, COMPUTER PROGRAM, AND INFORMATION PROCESSING APPARATUS

(71) Applicant: Tokyo Electron Limited, Tokyo (JP)

(72) Inventors: Ryoji ANZAKI, Tokyo (JP); Kei SANO, Austin, TX (US)

(73) Assignee: Tokyo Electron Limited, Tokyo (JP)

(21) Appl. No.: 19/182,748

(22) Filed: Apr. 18, 2025

Related U.S. Application Data
(63) Continuation of application No. PCT/JP2023/038325, filed on Oct. 24, 2023.

(30) Foreign Application Priority Data
Oct. 26, 2022 (JP) 2022-171575

(51) Int. Cl. G05B 19/418

(52) U.S. Cl. CPC G05B 19/41875; G05B 2219/32194; G05B 2219/45031

(57) ABSTRACT

Provided are an information processing method, a computer program, and an information processing apparatus that can be expected to effectively utilize data obtained from a substrate processing apparatus. An information processing method according to the present embodiment is executed by an information processing apparatus and includes acquiring time series observed data in which a state of a substrate processing apparatus is observed, and calculating parameters of a model that predicts, based on first observation information regarding the observed data at a first point in time, second observation information regarding the observed data at a second point in time after the first point in time, by dynamic mode decomposition based on the acquired time series observed data.

### CROSS-REFERENCE TO RELATED APPLICATIONS

This application is a bypass continuation application of international application No. PCT/JP2023/038325 having an international filing date of Oct. 24, 2023 and designating the United States, the international application being based upon and claiming the benefit of priority from Japanese Patent Application No. 2022-171575, filed on Oct. 26, 2022, the entire contents of each are incorporated herein by reference.

### TECHNICAL FIELD

The present disclosure relates to an information processing method, a computer program, and an information processing apparatus.

### BACKGROUND

Patent Document 1 proposes a state determination apparatus that generates a learning model by acquiring data related to an industrial machine, creating a plurality of partial time series data obtained by sliding time series data of physical quantities in data related to the industrial machine in a time axis direction based on the acquired data related to the industrial machine, extracting a plurality of learning data that include the plurality of partial time series data, and performing machine learning using the extracted learning data.

### CITATION LIST

### Patent Documents

Patent Literature 1: JP2020-128013A

### SUMMARY

The present disclosure is to provide an information processing method, a computer program, and an information processing apparatus that can be expected to effectively utilize data obtained from a substrate processing apparatus.

One embodiment relates to an information processing method executed by an information processing apparatus, the information processing method including: acquiring time series observed data in which a state of a substrate processing apparatus is observed; and calculating parameters of a model that predicts, based on first observation information regarding the observed data at a first point in time, second observation information regarding the observed data at a second point in time after the first point in time, by dynamic mode decomposition based on the acquired time series observed data.

According to the present disclosure, it can be expected to effectively utilize the data obtained from the substrate processing apparatus.

### BRIEF DESCRIPTION OF DRAWINGS

FIG. 1 is a schematic diagram illustrating an overview of an information processing system according to the present embodiment.

FIG. 2 is a block diagram illustrating a configuration example of an information processing apparatus according to the present embodiment.

FIG. 3 is a flowchart illustrating an example of a procedure of abnormality determination processing performed by the information processing apparatus according to the present embodiment.

FIG. 4 is a graph illustrating an example of time series observed temperature data.

FIG. 5 is a graph illustrating an example of internal state data obtained by dynamic mode decomposition.

FIG. 6 is a heat map illustrating an example of a matrix U obtained by the dynamic mode decomposition.

FIG. 7 is a flowchart illustrating an example of a procedure of information display processing performed by the information processing apparatus according to the present embodiment.

FIG. 8 is a schematic diagram illustrating an overview of an information processing system according to a modification example.

FIG. 9 is a schematic diagram illustrating a method of acquiring control input data and observed temperature data by an information processing apparatus according to Modification Example 2.

### DETAILED DESCRIPTION

Hereinafter, a specific example of an information processing system according to the embodiment of the present disclosure will be described with reference to the drawings. The present disclosure is not limited to these examples, and is defined by the claims, and is intended to include all modifications within the meaning and scope equivalent to the claims.

### <System Overview>

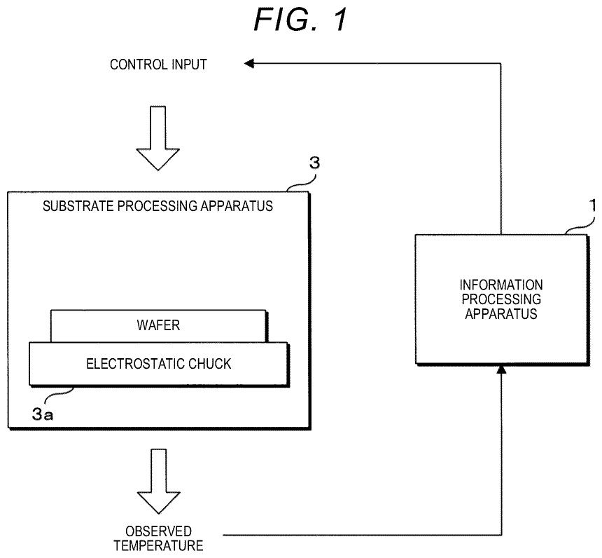

FIG. 1 is a schematic diagram illustrating an overview of the information processing system according to the present embodiment. The information processing system according to the present embodiment includes an information processing apparatus 1 and a substrate processing apparatus 3. The substrate processing apparatus 3 illustrated in the drawing is, for example, an apparatus such as a process chamber that performs processing such as etching on a wafer of a semiconductor. The substrate processing apparatus 3 includes, for example, an electrostatic chuck 3a for electrostatically fixing the wafer that is a processing target, a temperature control device (not illustrated) for controlling a temperature of the wafer, such as a chiller (cooling device) and/or a heater (heating device), and a sensor (not illustrated) that measures the temperature of the wafer.

The information processing apparatus 1 is an apparatus that performs control, monitoring, and the like of the operation of the substrate processing apparatus 3, and performs, in the present embodiment, temperature control of the substrate processing apparatus 3. The information processing apparatus 1 is connected to the substrate processing apparatus 3 through, for example, a communication line, a signal line, or the like, and supplies control input data to the temperature control device of the substrate processing apparatus 3, and acquires observed temperature data obtained by sensors of the substrate processing apparatus 3. The information processing apparatus 1 determines the control input data based on the observed temperature data acquired from the substrate processing apparatus 3, and supplies the control input data to the temperature control device of the substrate processing apparatus 3. Accordingly, the temperature of the wafer fixed to the electrostatic chuck 3a of the substrate processing apparatus 3 is controlled so that a desired temperature is maintained.

Further, in the present embodiment, the information processing apparatus 1 samples and acquires the control input data and the observed temperature data at a predetermined frequency, such as once a second or once a minute, when the wafer is being processed in the substrate processing apparatus 3. The information processing apparatus 1 stores the acquired control input data and observed temperature data, in a database. In the present embodiment, the information processing apparatus 1 inputs a plurality of control values as control data to the temperature control device of the substrate processing apparatus 3. Further, the substrate processing apparatus 3 is provided with a plurality of temperature sensors in order to observe a temperature distribution of the wafer, and the information processing apparatus 1 acquires the temperatures at a plurality of locations of the wafer measured by the plurality of temperature sensors as the observed temperature data. Therefore, in the present embodiment, the control input data and the observed temperature data stored in the database by the information processing apparatus 1 are multi-dimensional (two or more dimensions) vector information. The numbers of dimensions of the control input data and the observed temperature data may not be equal. Any one or both of the control input data and the observed temperature data may be a one-dimensional scalar value.

In the present embodiment, after the processing on the wafer is completed, for example, the information processing apparatus 1 determines the presence or absence of an abnormality or the like with respect to the processing performed on the wafer, the operation of the substrate processing apparatus 3, or the like, based on time series data of the control input data and the observed temperature data stored in the database. Further, when the abnormality is detected, for example, the information processing apparatus 1 displays various information based on the time series data stored in the database to assist the user in analyzing a cause of the abnormality or the like.

In the present embodiment, the information processing apparatus 1 uses a method of “dynamic mode decomposition” in order to perform, for example, the determination of the presence or absence of the abnormality and information display. The dynamic mode decomposition is a method of decomposing the time series data into a plurality of variation factors (modes), and a model that predicts the time series data can be generated by using the dynamic mode decomposition method. The generated model is a model that receives the observed data at a certain point in time as input, for example, and outputs a prediction value of the observed data at a subsequent point in time. The information processing apparatus 1 can determine parameters of the model that outputs the prediction values by performing processing of the dynamic mode decomposition using the time series data stored in the database. The dynamic mode decomposition is a known analysis method (see, for example, “Jonathan H. Tu, Clarence W. Rowley, Dirk M. Luchtenburg, Steven L. Brunton, J. Nathan Kutz. On dynamic mode decomposition: Theory and applications. Journal of Computational Dynamics, 2014, 1 (2): 391-421.”), and thus the detailed description thereof will be omitted.

For example, in the example illustrated in FIG. 1, the information processing apparatus 1 performs processing of the “dynamic mode decomposition” based on the time series observed temperature data by the sensors of the substrate processing apparatus 3. In this way, the information processing apparatus 1 can generate a model that receives the observed temperature data at a certain point in time as input, and outputs the prediction value of the observed temperature data at a subsequent point in time. The model generated by the information processing apparatus 1 does not need to be configured to receive and output the observed temperature data acquired from the substrate processing apparatus 3. The model may receive and output data obtained by performing some arithmetic processing (pre-processing) on the observed temperature data, such as an average value or a derivative value of the observed temperature data, for example. For example, the model may be configured to receive, as input, the average value of the observed temperature data at a certain point in time and within a predetermined time period before the point in time and output a prediction value of the average value of the observed temperature data at a subsequent point in time and within a predetermined time period before the point in time. Further, for example, the model may be configured to receive the first derivative value of the observed temperature data at a certain point in time as input, and output a prediction value of the first derivative value of the observed temperature data at a subsequent point in time. The model may have different types of input information and output information, and, for example, may be configured to receive, as input, the average value of the observed temperature data at a certain point in time, and output the prediction value of the first derivative value of the observed temperature data at a subsequent point in time.

Further, in the present embodiment, the information processing apparatus 1 uses a method of “dynamic mode decomposition with control input” in which the time series data of the control input can be additionally handled in the dynamic mode decomposition. By using the method of the dynamic mode decomposition with control input, the information processing apparatus 1 can generate a model that receives the control input data and the observed temperature data at a certain point in time as input, for example, and outputs the prediction value of observed temperature data at a subsequent point in time. The method of the dynamic mode decomposition with control input is a known analysis method (see, for example, “Joshua L. Proctor, Steven L. Brunton, J. Nathan Kutz. “Dynamic mode decomposition with control”, Sep. 24, 2014”), and thus the detailed description thereof will be omitted.

In the present embodiment, the information processing apparatus 1 performs processing of the “dynamic mode decomposition with control input” based on, for example, the control input data with respect to the substrate processing apparatus 3 and the observed temperature data from the substrate processing apparatus 3. In this way, the information processing apparatus 1 can generate a model that receives the control input data and the observed temperature data at a certain point in time as input, and outputs the prediction value of the observed temperature data at a subsequent point in time. The control input data input to the model may be data obtained by performing some arithmetic processing on the data input to the substrate processing apparatus 3, such as an average value or a first derivative value, similarly to the model that outputs the prediction value of the observed temperature data. Even when the “dynamic mode decomposition” is simply described, the following description includes “dynamic mode decomposition with control input”.

The information processing apparatus 1 performs the dynamic mode decomposition with control input based on the control input data and the observed temperature data acquired when the substrate processing apparatus 3 is performing processing on one wafer and stored in the database. In this way, the information processing apparatus 1 can obtain internal parameters of a model that receives the control input data and the observed temperature data at a certain point in time as input, and outputs the prediction value of the observed temperature data at a subsequent point in time. The information processing apparatus 1 compares the obtained parameters of the model with, for example, the parameters of the model determined using data collected for normally processed wafers or the parameters of the model determined using data collected when the abnormality occurs in the processing. With this configuration, the information processing apparatus 1 can determine the presence or absence of the abnormality with respect to the wafer processed this time.

Further, the information processing apparatus 1 can provide the user with the parameters of the model obtained by performing the dynamic mode decomposition in a visualized manner, for example, by graphing and displaying the parameters. The parameters obtained by performing the dynamic mode decomposition express the characteristics (modes) of the data that is the processing target. Based on the obtained parameters, the information processing apparatus 1 according to the present embodiment can perform visualization, such as creating and displaying a graph illustrating, for example, the characteristics of the mode, and creating and displaying a heat map illustrating, for example, a relationship between the mode and the original data in a matrix form.

### <Apparatus Configuration>

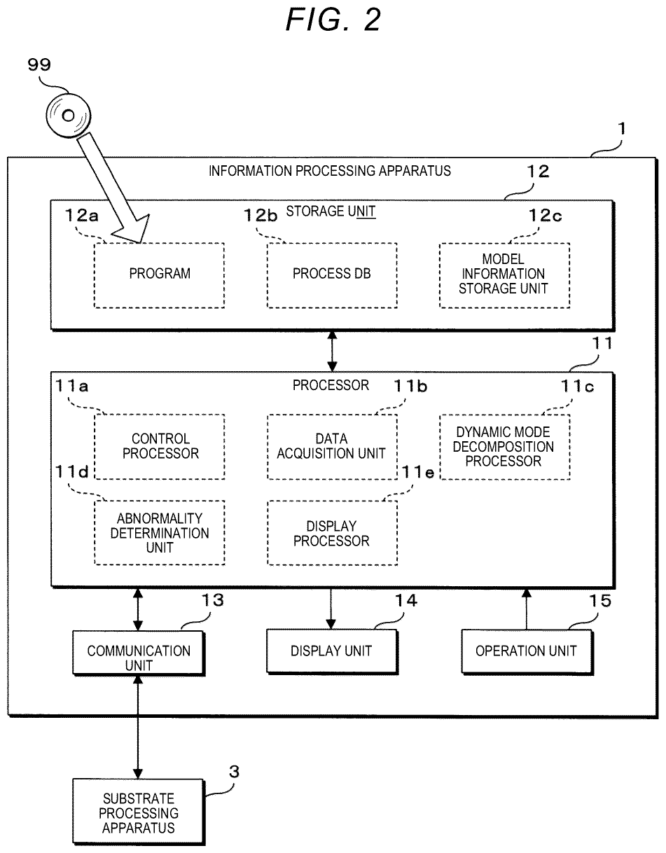

FIG. 2 is a block diagram illustrating a configuration example of the information processing apparatus 1 according to the present embodiment. The information processing apparatus 1 according to the present embodiment includes a processor 11, a storage unit 12, a communication unit 13, a display unit 14, an operation unit 15, and the like. In the present embodiment, an example will be described in which a process is performed by one information processing apparatus 1. Meanwhile, the process of the information processing apparatus 1 may be distributed and performed by a plurality of apparatuses.

The processor 11 is configured by using an arithmetic processing apparatus such as a central processing unit (CPU), a micro-processing unit (MPU), a graphics processing unit (GPU), or a quantum processor, a read only memory (ROM), a random access memory (RAM), and the like. The processor 11 reads and executes a program 12a stored in the storage unit 12, thereby performing various processing such as processing of controlling the operation of the substrate processing apparatus 3 and processing of detecting the abnormality or the like in the substrate processing apparatus 3. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

The storage unit 12 is configured by using, for example, a large-capacity storage apparatus such as a hard disk. The storage unit 12 stores various types of programs to be executed by the processor 11 and various types of data necessary for the process of the processor 11. In the present embodiment, the storage unit 12 stores the program 12a to be executed by the processor 11. Further, the storage unit 12 includes a process DB 12b that stores and accumulates the control input data and the observed temperature data, and a model information storage unit 12c that stores the parameters and the like of the model generated by the processing of the dynamic mode decomposition using these pieces of data.

In the present embodiment, the program (computer program, program product) 12a is provided in a form recorded on a recording medium 99 such as a memory card or an optical disc. The information processing apparatus 1 reads the program 12a from the recording medium 99, and stores the program 12a in the storage unit 12. However, for example, the program 12a may be written into the storage unit 12 during a manufacturing stage of the information processing apparatus 1. For example, as the program 12a, the information processing apparatus 1 may acquire those which are distributed by a remote server device or the like through communication. For example, the program 12a may be written into the storage unit 12 of the information processing apparatus 1 after a writing apparatus reads program recorded in the recording medium 99. The program 12a may be provided in the form of distribution through a network, or may be provided in the form recorded in the recording medium 99.

The process DB 12b in the storage unit 12 is a database that stores and accumulates data acquired by sampling the control input data with respect to the substrate processing apparatus 3 and the observed temperature data from the substrate processing apparatus 3 by the information processing apparatus 1. The process DB 12b stores the control input data and the observed temperature data, and various information such as, for example, a date and time of acquisition of the data and identification information of the wafer that is the processing target, in association with each other. Further, the process DB 12b may store the determination results of normal/abnormal (non-defective product/defective product) determined by measuring the characteristics of the wafer or the like after the processing by the substrate processing apparatus 3 is completed, for example.

The model information storage unit 12c stores information such as the parameters of the model obtained by the information processing apparatus 1 performing the processing of the dynamic mode decomposition using the control input data and the observed temperature data stored in the process DB 12b. In the present embodiment, the information processing apparatus 1 performs the processing of the dynamic mode decomposition using the acquired control input data and observed temperature data for each wafer processed by the substrate processing apparatus 3 to generate a model, and stores the parameters of the generated model in the model information storage unit 12c. The model information storage unit 12c may store the parameters of the model generated through the dynamic mode decomposition, and various information such as the date and time when the information is stored and the identification information of the wafer that is the processing target, in association with each other. Further, for example, the model information storage unit 12c may store information such as the result of the abnormality determination performed based on the parameters of the model.

The communication unit 13 is connected to the substrate processing apparatus 3 through a cable such as a communication line or a signal line, and transmits and receives data to and from the substrate processing apparatus 3 through the cable. In the present embodiment, the communication unit 13 transmits the control input data supplied from the processor 11 to the substrate processing apparatus 3. Further, the communication unit 13 receives the observed temperature data transmitted from the substrate processing apparatus 3, and supplies the received observed temperature data to the processor 11.

The display unit 14 is configured by using a liquid crystal display or the like, and displays various images, characters, and the like based on the process of the processor 11. In the present embodiment, the display unit 14 displays, for example, various information relating to an operation state of the substrate processing apparatus 3, and displays various information obtained through the dynamic mode decomposition.

The operation unit 15 receives a user operation and notifies the processor 11 of the received operation. For example, the operation unit 15 receives the user operation by an input device such as a mechanical button or a touch panel provided on a surface of the display unit 14. For example, the operation unit 15 may be an input device such as a mouse and a keyboard, and these input devices may be configured to be detachable from the information processing apparatus 1.

The storage unit 12 may be an external storage device connected to the information processing apparatus 1. The information processing apparatus 1 may be a multi-computer including a plurality of computers, or may be a virtual machine virtually constructed by software. In addition, the information processing apparatus 1 is not limited to the configuration described above, and does not need to include the display unit 14, the operation unit 15, and the like, for example.

In the information processing apparatus 1 of the present embodiment, the processor 11 reads and executes the program 12a stored in the storage unit 12, so that a control processor 11a, a data acquisition unit 11b, a dynamic mode decomposition processor 11c, an abnormality determination unit 11d, a display processor 11e, and the like are implemented as software-like functional units in the processor 11.

The control processor 11a performs processing of controlling the operation of the substrate processing apparatus 3 by performing, for example, the generation of the control input data and the transmission of the control input data to the substrate processing apparatus 3 in accordance with a predetermined semiconductor manufacturing procedure. For example, the control processor 11a supplies, as the control input data, data such as an amount of increase or decrease in temperature or an amount of operation of the apparatus, to the temperature control device such as one or more heaters and chillers provided in the substrate processing apparatus 3. In this way, the information processing apparatus 1 can perform the temperature control of the wafer processed by the substrate processing apparatus 3.

The data acquisition unit 11b performs processing of acquiring the control input data input by the control processor 11a to the substrate processing apparatus 3 and the observed temperature data measured by one or more temperature sensors provided in the substrate processing apparatus 3. The data acquisition unit 11b samples and acquires these pieces of data at predetermined intervals such as once per second or once per minute, for example. The data acquisition unit 11b stores the acquired control input data and observed temperature data and the date and time of acquisition of the data and the identification information of the wafer that is the processing target, in association with each other in the process DB 12b. The data acquisition unit 11b acquires data at predetermined intervals and stores the data in the process DB 12b, so that the time series data of the control input data and the observed temperature data are accumulated in the process DB 12b.

The dynamic mode decomposition processor 11c performs the processing of the dynamic mode decomposition based on the time series control input data and observed temperature data acquired by the data acquisition unit 11b and stored in the process DB 12b. For example, after the processing of one wafer by the substrate processing apparatus 3 is completed, the dynamic mode decomposition processor 11c reads, from the process DB 12b, the time series control input data and observed temperature data acquired and stored when processing the one wafer. The dynamic mode decomposition processor 11c performs the dynamic mode decomposition based on the read time series data. The dynamic mode decomposition processor 11c may perform the dynamic mode decomposition using only the observed temperature data, or the dynamic mode decomposition with control input using the control input data and the observed temperature data. Which dynamic mode decomposition is performed by the dynamic mode decomposition processor 11c may be determined, for example, by the user's selection. The dynamic mode decomposition processor 11c stores the parameters of the model obtained by the processing of the dynamic mode decomposition in the model information storage unit 12c.

The abnormality determination unit 11d performs processing of determining whether the abnormality has occurred when the substrate processing apparatus 3 processes the wafer corresponding to the time series data used for the dynamic mode decomposition, based on the parameters of the model obtained by dynamic mode decomposition. In the present embodiment, the time series data (control input data and observed temperature data) are collected in advance for each of a case where the wafer is normally processed and a case where the abnormality occurs. Then, the dynamic mode decomposition is performed on the time series data for each processing on one wafer, and the processing of acquiring the parameters of the model is performed in advance. Based on the parameters at the time of normality and the parameters at the time of abnormality that are obtained in advance, a threshold of the parameters for distinguishing between the normality and the abnormality is determined in advance, and the threshold is stored as the determination condition in the storage unit 12 of the information processing apparatus 1. The abnormality determination unit 11d compares the parameter obtained through the dynamic mode decomposition of the dynamic mode decomposition processor 11c with a predetermined threshold to determine the presence or absence of an abnormality with respect to the processing performed on the wafer this time.

The parameters obtained by the dynamic mode decomposition are vectors or matrices each including a plurality of values. The threshold for determining the abnormality is determined for each component of the vector or the matrix, for example. When it is determined that there is the abnormality by comparing the at least one of the parameter components with the threshold, the abnormality determination unit 11d can determine that there is the abnormality in the processing performed on the wafer. Further, for example, one threshold may be set for the total value, the average value, or the like of the plurality of values included in the parameter. Further, for example, the abnormality determination may be performed using a value characterizing the parameter, such as a singular value or an eigenvalue of the parameter. Further, for example, data obtained by associating a correct answer flag indicating the presence or absence of the abnormality with the parameter calculated by the dynamic mode decomposition based on the time series data collected in advance can be used as training data. It is possible to generate an abnormality determination model that outputs the presence or absence of the abnormality in response to the input of the parameter, by performing so-called supervised machine learning using the training data. The abnormality determination unit 11d may perform the determination using such an abnormality determination model.

The display processor 11e performs processing of displaying, on the display unit 14, various information such as various information relating to control processing by the control processor 11a and information relating to the abnormality determination result by the abnormality determination unit 11d. Further, in the present embodiment, the display processor 11e performs processing of displaying the parameters of the model obtained by the processing of the dynamic mode decomposition of the dynamic mode decomposition processor 11c in a visualized manner on the display unit 14. The display processor 11e can display, for example, a graph illustrating the characteristics of the mode included in the parameters of the model on the display unit 14. The display processor 11e can display, for example, a heat map illustrating a relationship between the mode and the original time series data in a matrix form on the display unit 14. Further, the display processor 11e may perform any display other than these displays.

### <Dynamic Mode Decomposition>

Hereinafter, the dynamic mode decomposition will be briefly described. The model generated in the dynamic mode decomposition with control input is expressed by the following Equation (1). In Equation (1), X is a vector of the observed temperature data, and Y is a vector of the control input data. In Equation (1), A and B are matrices and are parameters calculated by the dynamic mode decomposition.

$$\begin{matrix}[ Equation 1 ] & \\ {XD}_{π} = AX + B Υ & ( 1 )\end{matrix}$$

Further, the left side of Equation (1) expresses data obtained by performing some sort of transformation D, on the observed temperature data X. Here, a case is assumed in which a first derivative D⁽¹⁾ expressed by the following equation (2) is adopted as the transformation D_{π}, and the matrix B is 0. However, the D, shown in Equation (2) is merely an example, and is not limited to this example.

$$\begin{matrix}[ Equation 2 ] & \\ {D}^{( 1 )} = \frac{1}{Δ t} ( \begin{matrix}- 1 & + 1 & 0 & … \\ 0 & - 1 & + 1 & … \\ ⋮ & ⋮ & ⋮ & ⋮ \\ 0 & … & - 1 & + 1\end{matrix} ) & ( 2 )\end{matrix}$$

Accordingly, the above Equation (1) can be transformed into the following Equation (3).

$$\begin{matrix}[ Equation 3 ] & \\ {XD}^{( 1 )} = AX & ( 3 )\end{matrix}$$

Here, assuming that observed temperature data X=[x₀, x₁, . . . , x_{T}], the above Equation (3) becomes an equation having a form as the following Equation (4). Here, xₜ is, for example, a dimensional vector equal to the number of sensors provided in the substrate processing apparatus 3, and is (t=0, 1, . . . , T).

$$\begin{matrix}[ Equation 4 ] & \\ {x}_{t + 1} = {Ax}_{t} & ( 4 )\end{matrix}$$

Further, when X_{0:T}=[x₀, x₁, . . . , X_{T-1}] and X_{1:T+1}=[x₁, x₂, . . . , X_{T}], the above Equation (4) becomes the following Equation (5).

$$\begin{matrix}[ Equation 5 ] & \\ {X}_{1 : T + 1} = {AX}_{0 : T} & ( 5 )\end{matrix}$$

In the dynamic mode decomposition, the parameters of the model can be calculated by calculating the matrix A that satisfies Equation (5) based on the two matrices X_{0:T} and X_{1:T+1} created from the observed temperature data X.

In the present embodiment, a method of calculating the matrix A, which is the parameter, for when B=0 in Equation (1), that is, for general dynamic mode decomposition (without control input) has been described. Although the detailed description for the method of calculating the parameters A and B when B is not 0, that is, when the dynamic mode decomposition with control input is performed will be omitted, the parameters A and B can be calculated in the same manner.

The calculation of the parameters based on the above arithmetic expression is an example of the dynamic mode decomposition (DMD), and is not limited thereto. The dynamic mode decomposition includes various variations such as a Hankel DMD, a resDMD, an optimized DMD (optDMD), and a bagging-optimized DMD (BOP-DMD), and the information processing apparatus 1 may calculate the parameters by using these various dynamic mode decomposition techniques. The Hankel DMD is a dynamic mode decomposition method of using a vector obtained by combining values in a plurality of time steps as a state vector, thereby improving the acquisition of historical effects and the estimation of the parameters. The resDMD is a method of utilizing dynamic mode decomposition as a reference term of residual neural networks (ResNet). The optDMD is a dynamic mode decomposition method in which a modeling system is improved by using a nonlinear optimization framework in order to solve the bias caused by noise in data. The BOP-DMD is a dynamic mode decomposition method in which robustness is improved by randomly extracting snapshots of time series data to configure subsets, and performing ensemble by applying the optDMD to each subset.

In the method of the dynamic mode decomposition by the information processing system according to the present embodiment, it is possible to perform prediction of a medium- to long-term section without being limited to a period ahead, and it is possible to perform optimization of the parameters or the like based on the prediction results. When a dominant equation (for example, the above Equation (1)) has a simple configuration, it is possible to perform medium-to-long-term prediction with higher accuracy. For example, a temperature change during a semiconductor surface processing process can be predicted from the start to the end of the processing, and the optimum parameter can be determined from a plurality of parameter candidates based on evaluation indicators determined by the user. The parameters used herein include parameters for correcting a difference between machines, such as heaters and temperature sensors.

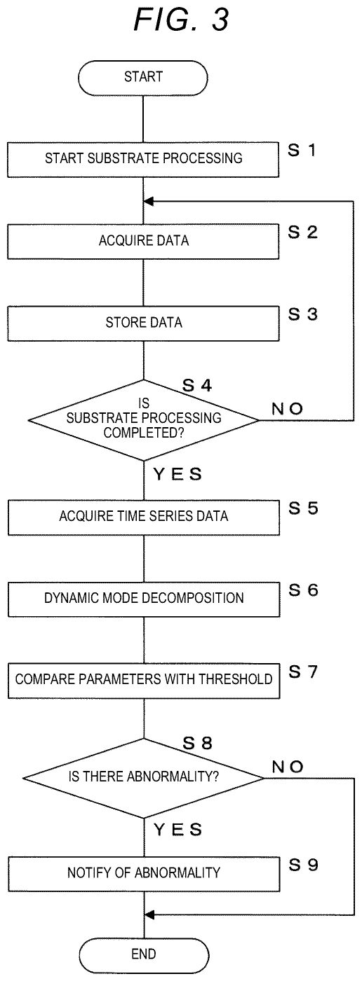

FIG. 3 is a flowchart illustrating an example of a procedure of abnormality determination processing performed by the information processing apparatus 1 according to the present embodiment. The control processor 11a of the processor 11 of the information processing apparatus 1 according to the present embodiment starts the substrate processing such as etching on the wafer when receiving an operation for starting the processing by the user, for example (step S1).

The data acquisition unit 11b of the processor 11 acquires the control input data input to the substrate processing apparatus 3 and the observed temperature data observed by the sensors of the substrate processing apparatus 3 (step S2). The data acquisition unit 11b stores the control input data and observed temperature data acquired in step S2 and information such as the date and time of acquisition of the data and the identification information of the wafer that is the processing target, in association with each other in the process DB 12b (step S3).

The data acquisition unit 11b determines whether the substrate processing being performed on the wafer has been completed (step S4). When the substrate processing has not been completed (S4: NO), the data acquisition unit 11b returns the processing to step S2, and repeats the acquisition and storage of data.

When the substrate processing is completed (step S4: YES), the data acquisition unit 11b reads and acquires the time series control input data and observed temperature data stored in the process DB 12b in a period from the start to the end of the substrate processing on the wafer (step S5).

The dynamic mode decomposition processor 11c of the processor 11 performs the processing of the dynamic mode decomposition based on the time series control input data and observed temperature data acquired in step S5 (step S6). In this case, the dynamic mode decomposition processor 11c may perform the processing of the dynamic mode decomposition with control input using both the control input data and the observed temperature data, or may perform the processing of the dynamic mode decomposition without control input using only the observed temperature data. Which processing is to be performed by the dynamic mode decomposition processor 11c may be determined based on, for example, the user's selection.

The abnormality determination unit 11d of the processor 11 compares the parameters of the model that receives, as input, the time series data at a certain point in time obtained by the processing of the dynamic mode decomposition performed in step S6 and predicts the time series data at a subsequent point in time, with a predetermined threshold (step S7). The abnormality determination unit 11d determines the presence or absence of the abnormality in the substrate processing performed this time, based on the comparison between the parameters (the matrices A and B or only the matrix A of the above Equation (1)) of the model and the threshold (step S8). When there is the abnormality (S8: YES), the display processor 11e of the processor 11 notifies the user of the abnormality by displaying a message or the like indicating the detection of the abnormality on the display unit 14 (step S9), and ends the processing. When there is no abnormality (S8: NO), the processor 11 ends the processing. Step S9 can include correcting the abnormality (or abnormalities) For instance, in response to determining an abnormality, parameters can be adjusted in subsequent substrate processing and/or transferring of the wafer.

### <Information Display>

In the dynamic mode decomposition performed by the information processing apparatus 1 according to the present embodiment, the parameters of the model can be calculated based on the time series data, and the dimensions of the time series data can be reduced, as described above. When the information processing apparatus 1 performs dimension reduction by the dynamic mode decomposition, the dimension-reduced data (modes) expressing the characteristics of the original time series data and a matrix indicating a correspondence relationship between the dimension-reduced data and the original time series data are obtained. Hereinafter, in the present embodiment, this dimension-reduced data will be referred to as “internal state data” by deeming the dimension-reduced data to be data that approximately indicates the internal state of the substrate processing apparatus 3.

The observed temperature data X_{0:T}=[x₀, x₁, . . . , x_{T-1}] of the time series used in the above Equation (5) can be decomposed into three matrices as shown in the following Equation (6) by performing singular value decomposition. In Equation (6), Σ is a matrix of singular values, U is a unitary matrix, and V* is an accompanying matrix of the unitary matrix V.

$$\begin{matrix}[ Equation 6 ] & \\ {X}_{0 : T} = U \sum {V}^{*} & ( 6 )\end{matrix}$$

In Equation (6), ΣV* corresponds to the above-described internal state data, and U corresponds to a matrix indicating the relationship between the observed temperature data and the internal state data. The correspondence relationship between these matrices and the parameter A shown in the above Equation (5) is expressed by the following Equation (7).

$$\begin{matrix}[ Equation 7 ] & \\ A = {X}_{1 : T + 1} V {\sum }^{- 1} {U}^{*} & ( 7 )\end{matrix}$$

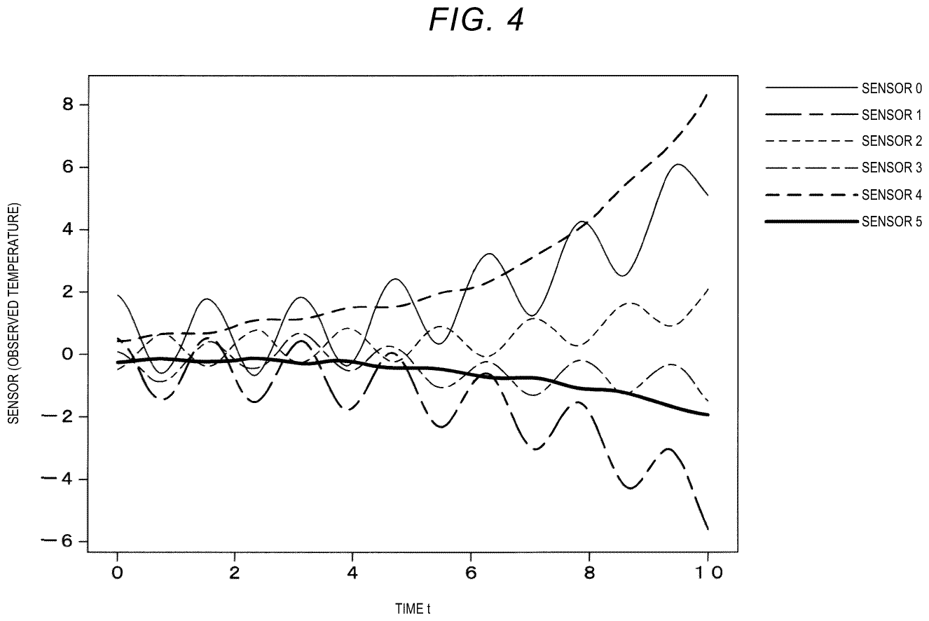

FIG. 4 is a graph illustrating an example of the time series observed temperature data. In the present example, the substrate processing apparatus 3 is provided with six temperature measurement sensors. In the illustrated graph, a horizontal axis is a time t, and a vertical axis is the observed temperature measured by six sensors 0 to 5. The information processing apparatus 1 can create the illustrated graph based on the observed temperature data periodically acquired from the substrate processing apparatus 3 and accumulated in the process DB 12b, and display the graph on the display unit 14. The graph corresponds to a graph of X_{0:T} in Equation (6).

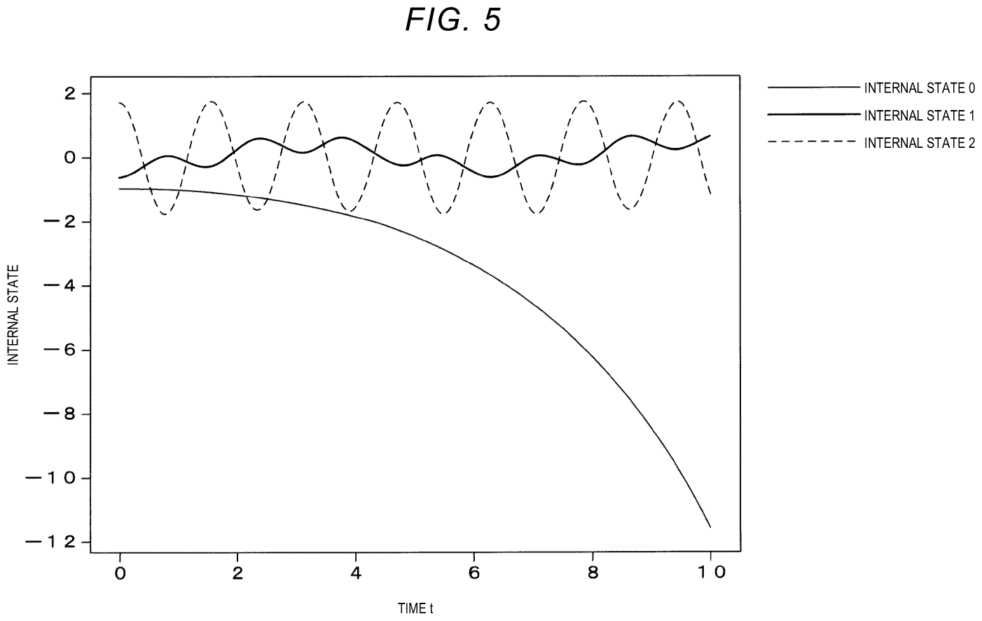

FIG. 5 is a graph illustrating an example of the internal state data obtained by the dynamic mode decomposition. In the illustrated graph, a horizontal axis is a time t, and a vertical axis is a numerical value illustrating the internal state of the substrate processing apparatus 3. The internal state data illustrated in FIG. 5 is data acquired by the processing of the dynamic mode decomposition based on the observed temperature data illustrated in FIG. 4. In the present example, the six observed temperature data are dimension-reduced to three internal state data.

The information processing apparatus 1 can perform the processing of the dynamic mode decomposition based on observed temperature data periodically acquired from the substrate processing apparatus 3 and accumulated in the process DB 12b, thereby acquiring the dimension-reduced internal state data. The information processing apparatus 1 can create the illustrated graph based on the internal state data and display the graph on the display unit 14. The graph corresponds to a graph of ΣV* in Equation (6). Using the matrix U in the above Equation (6), the relationship between the observed temperature data xₜ and the internal state data yₜ is expressed by the following Equation (8).

$$\begin{matrix}[ Equation 8 ] & \\ {y}_{t} = {U}^{*} {x}_{t} & ( 8 )\end{matrix}$$

When an equation that expresses the time evolution of the internal state of the substrate processing apparatus 3 is obtained based on Equation (8), the following Equation (9) is obtained.

$$\begin{matrix}[ Equation 9 ] & \\ {y}_{t + 1} = {U}^{*} {X}_{1 : T + 1} V {\sum }^{- 1} {y}_{t} & ( 9 )\end{matrix}$$

By using the matrix U*X_{1:T+1}VΣ⁻¹ included in Equation (9), the information processing apparatus 1 can create the graph illustrated in FIG. 5.

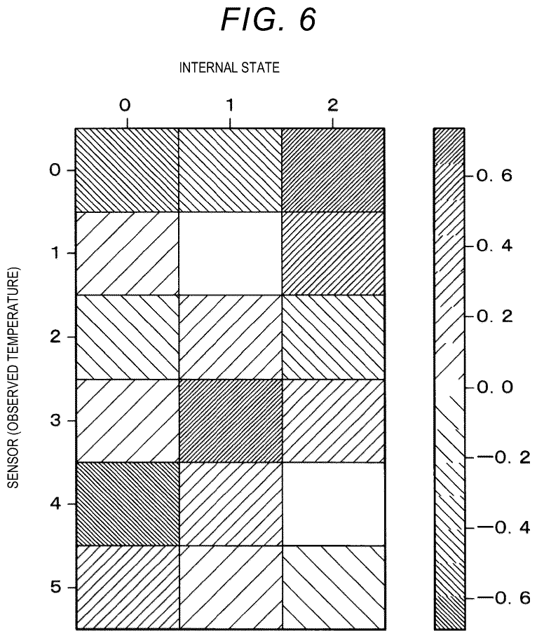

FIG. 6 is a heat map illustrating an example of the matrix U obtained by the dynamic mode decomposition. This example is a heat map illustrating the correspondence relationship between the six observed temperature data shown in FIG. 4 and the three internal state data shown in FIG. 5 in blocks arranged in a 6×3 matrix. The heat map expresses the observed temperature data obtained by the six sensors 0 to 5 in the vertical direction, expresses three internal state data in the horizontal direction, and expresses the relationship (correlation) between the observed temperature data and the internal state data to which the colors of the blocks corresponding to the vertical and horizontal intersections correspond.

In the present example, the information processing apparatus 1 can calculate the matrix U having a size of 6×3 by the dynamic mode decomposition. The information processing apparatus 1 can create the heat map shown in FIG. 6 by coloring the blocks arranged in a 6×3 matrix with the type and shade of color corresponding to the values of each element included in the matrix U. The information processing apparatus 1 can determine the type of color depending on whether the value of the matrix U corresponding to each block is positive or negative, and can determine the shade of color depending on the magnitude of the absolute value of this value. The information processing apparatus 1 can create the heat map based on the matrix U obtained by the dynamic mode decomposition, and display the heat map on the display unit 14. In FIG. 6, the respective blocks of the heat map are hatched, the types of colors are expressed by hatching orientations, and the shades of colors are expressed by the densities of the hatched lines.

In the illustrated heat map, for example, the observed temperature data of the sensor 0 has a large relationship in a negative direction with the internal states 0 and 1, and a large relationship in a positive direction with the internal state 2. Further, for example, the observed temperature data of the sensor 5 has a large relationship in the positive direction with the internal state 0, and does not have any relationship with the internal states 1 and 2.

Each graph of the observed temperature data illustrated in FIG. 4 can be approximately generated based on the graph of the internal state data illustrated in FIG. 5 and the heat map illustrated in FIG. 6. For example, the graph of the observed temperature data of the sensor 0 corresponds to the sum of the value of the block corresponding to the sensor 0 and the internal state 0 in the heat map multiplied by the graph of the internal state 0, the value of the block corresponding to the sensor 0 and the internal state 1 in the heat map multiplied by the graph of the internal state 1, and the value of the block corresponding to the sensor 0 and the internal state 2 in the heat map multiplied by the graph of the internal state 2. The same applies to the graphs of the observed temperature data of the other sensors.

The user can expect to estimate the cause of the abnormality, for example, by comparing the graph and the heat map obtained by performing the dynamic mode decomposition based on the observed data during the processing of the wafer determined to be normal, and the graph and the heat map obtained by performing the dynamic mode decomposition based on the observed data during the processing of the wafer determined to be abnormal.

Similarly, the information processing apparatus 1 can, for example, store the graph and heat map created based on the observed data during the processing of the wafer determined to be normal or abnormal in the past and perform processing of estimating the cause of the abnormality or the like based on the difference from the graph and heat map generated this time. Instead of creating and comparing the graph and the heat map, the information processing apparatus 1 may compare information for creating the graph and the heat map, that is, the internal state data and the matrix or the like indicating the relationship between the observed temperature data and the internal state data.

For example, with respect to the graph of the internal state data illustrated in FIG. 5, when there is a difference between the normal state and the abnormal state, the user or the information processing apparatus 1 can estimate that there is the cause of the abnormality or the like in the internal state of the substrate processing apparatus 3. Further, for example, with respect to the heat map illustrated in FIG. 6, when there is a difference between the normal state and the abnormal state, the user or the information processing apparatus 1 can estimate that the abnormality has the cause peculiar to the sensor.

In the present example, the method of displaying the graph and the heat map when B=0 in Equation (1), that is, for the general dynamic mode decomposition (without control input), has been described. Although the detailed description thereof will be omitted, the graph and the heat map can be displayed in the same manner also when B is not 0, that is, the dynamic mode decomposition with control input is performed.

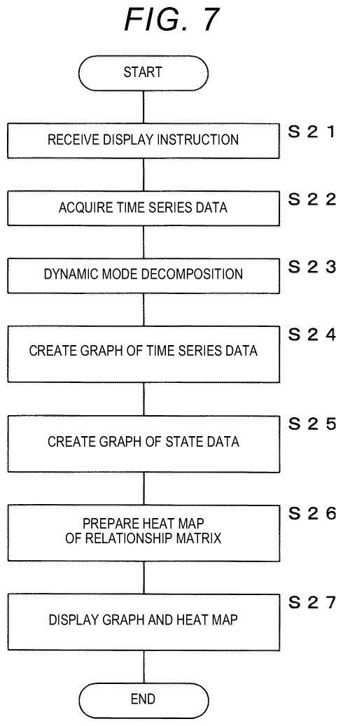

FIG. 7 is a flowchart illustrating an example of a procedure of information display processing performed by the information processing apparatus 1 according to the present embodiment. The processor 11 of the information processing apparatus 1 according to the present embodiment starts the information display processing when receiving an instruction for information display from the user, for example (step S21). The data acquisition unit 11b of the processor 11 reads and acquires the time series control input data and observed temperature data stored in the process DB 12b in a period from the start to the end of the substrate processing on the wafer that is the display target (step S22).

The dynamic mode decomposition processor 11c of the processor 11 performs the processing of the dynamic mode decomposition based on the time series control input data and observed temperature data acquired in step S22 (step S23). In this case, the dynamic mode decomposition processor 11c may perform the processing of the dynamic mode decomposition with control input using both the control input data and the observed temperature data, or may perform the processing of the dynamic mode decomposition without control input using only the observed temperature data. Which processing is to be performed by the dynamic mode decomposition processor 11c may be determined based on, for example, the user's selection.

The display processor 11e of the processor 11 creates, for example, the graph of the time series observed temperature data acquired in step S22 (step S24). The display processor 11e also creates the graph of the internal state data (data obtained by dimension-reducing the observed temperature data) of the substrate processing apparatus 3 obtained by the processing of the dynamic mode decomposition of step S23 (step S25). The display processor 11e also creates the heat map based on the matrix U indicating the relationship between the observed temperature data and the internal state data obtained by the processing of the dynamic mode decomposition in step S23 (step S26). The display processor 11e displays the graphs created in steps S24 and S25 and the heat map created in step S26 on the display unit 14 (step S27), and ends the processing.

### MODIFICATION EXAMPLES

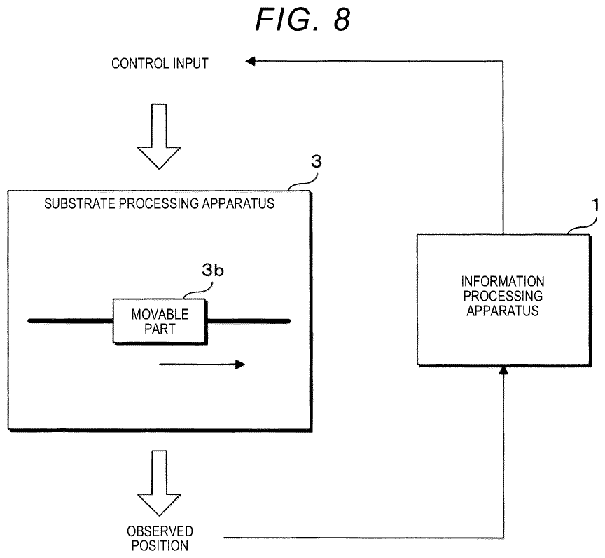

In the above-described embodiment, the temperature control of the substrate processing apparatus 3 has been described as an example, but the application of the present technology is not limited to the temperature control. FIG. 8 is a schematic diagram illustrating an overview of an information processing system according to a modification example. The information processing system according to the modification example is, for example, a system that performs abnormality determination or the like with respect to the substrate processing apparatus 3 that is configured to transfer a wafer.

The substrate processing apparatus 3 according to the modification example includes the transfer mechanism that transfers the wafer. The transfer mechanism includes a movable part 3b that moves according to an operation of, for example, an actuator or a motor. The substrate processing apparatus 3 drives the actuator, the motor, or the like in accordance with the control input data from the information processing apparatus 1, and the movable part 3b moves in response thereto to transfer the wafer.

Further, the substrate processing apparatus 3 includes a sensor or the like that measures a position. The information processing apparatus 1 acquires a measurement result of the position of the movable part 3b by the sensor of the substrate processing apparatus 3 as the observed position data at predetermined intervals. In the present modification example, the sensor measures the position of the movable part 3b, but the present disclosure is not limited to this configuration, and the sensor may measure, for example, the speed, acceleration, or the like of the movable part 3b. Further, in a case where the movable part 3b is a part that rotates, for example, the rotation speed, the angular velocity, or the like may be measured by the sensor. Further, the information processing apparatus 1 may acquire video data of the movable part 3b captured by a camera, instead of the sensor. Further, the information processing apparatus 1 may acquire a combination of the plurality of pieces of information.

The information processing apparatus 1 acquires the control input data and the observed position data at predetermined intervals, and stores the acquired control input data and observed position data in the process DB 12b. After the transfer of the wafer by the substrate processing apparatus 3 is completed, the information processing apparatus 1 can perform the dynamic mode decomposition based on the time series control input data and observed position data stored in the process DB 12b.

Further, the application of the present technology is not limited to the temperature control and the wafer transfer control. The present technology can be applied to control relating directly or indirectly to a state of the substrate processing apparatus 3.

### Modification Example 2

In the above-described embodiment, the information processing apparatus 1 acquires the control input data and the observed temperature data by sampling the input/output signals to the substrate processing apparatus 3 at predetermined intervals. However, the acquisition of the control input data, the observed temperature data, and the like is not limited to the periodic sampling.

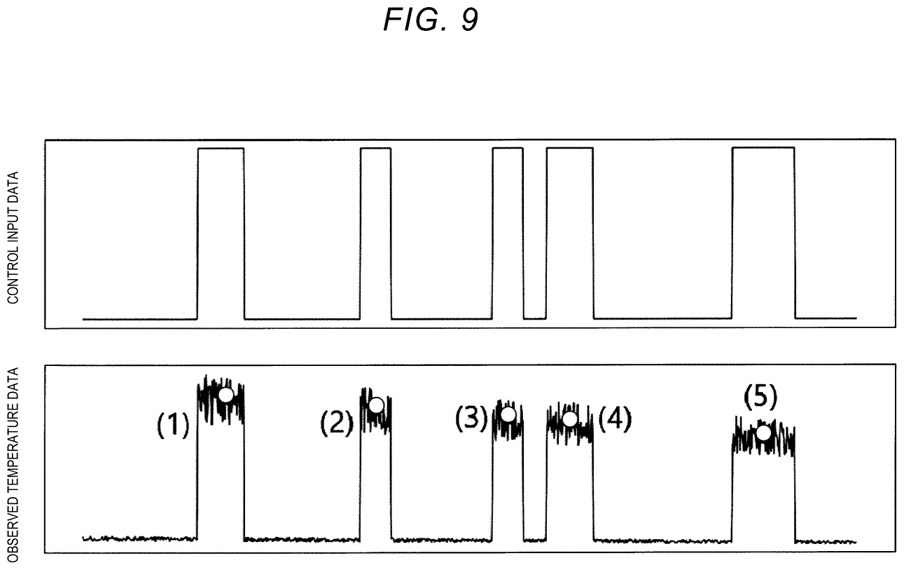

FIG. 9 is a schematic diagram illustrating a method of acquiring control input data and observed temperature data by an information processing apparatus 1 according to Modification Example 2. In the information processing system according to Modification Example 2, the information processing apparatus 1 inputs pulse-shaped signals as shown in the upper portion of FIG. 9 to the substrate processing apparatus 3 as the control input data. The control input data controls a timing of applying a laser, heat, or the like in a pulse-shaped manner during the surface processing of the substrate, for example, and the substrate processing apparatus 3 performs processing such as a laser in response to the input of the high level signal. Further, the control input data of the present example is a signal that non-periodically repeats changes between the high level and the low level.

In this example, the information processing apparatus 1 needs to acquire the observed data such as the temperature observed by the sensor or the like when processing such as a laser is performed in the substrate processing apparatus 3, and does not need to acquire the observed data when processing is not performed. The information processing apparatus 1 according to Modification Example 2 acquires the observed temperature data when the control input data is in a predetermined state, that is, when the control input data is at the high level in the present example. The control input data illustrated in FIG. 9 includes five periods (1) to (5) in which the signal becomes the high level, and the information processing apparatus 1 can acquire the five values of (1) to (5) by acquiring the observed temperature data in each high level period, and use these values as the time series observed temperature data in the order in which the values are acquired.

The information processing apparatus 1 may perform the data acquisition a plurality of times in each high level period, calculate a representative value such as the average value or the median value of the plurality of obtained values, and use these values as the observed temperature data for one round. Further, the information processing apparatus 1 may perform the data acquisition a plurality of times for each period in which the control input data becomes the high level, and separately use these pieces of data as the time series observed temperature data.

### Modification Example 3

The information processing apparatus 1 according to the present embodiment repeatedly acquires the control input data input to the substrate processing apparatus 3 and the observed temperature data obtained by observing the substrate processing apparatus 3, and performs the processing of the dynamic mode decomposition based on these pieces of time series data to generate the prediction model. In this case, the information processing apparatus 1 may perform various types of pre-processing on the time series data (control input data and/or observed temperature data) used for the dynamic mode decomposition. Hereinafter, some of the pre-processing that can be performed by the information processing apparatus 1 will be described.

### Removal of Low Frequency Disturbance

The low-frequency disturbances such as offsets or drifts may cause the low-frequency disturbances due to various factors such as the operation at the equilibrium point and the temperature-dependent characteristics of the sensor, which may deteriorate the modeling accuracy. Therefore, the information processing apparatus 1 can eliminate the low-frequency disturbances by, for example, performing calculations such as calculating an average value based on the acquired time series data, subtracting data using advance information about an equilibrium point, or calculating a difference between data as the pre-processing.

### Removal of High Frequency Disturbance

By removing the influence of noise that is not the target of the modeling or the frequency domain included in the time series data, such as the dynamics of the high frequency band, it can be expected to improve the signal-to-noise (SN) ratio and improve the modeling accuracy. The information processing apparatus 1 can remove high frequency disturbance by applying, for example, a filter that attenuates a high frequency band in the frequency domain, such as a low-pass filter or a moving average filter.

### Removal of Outlier or Missing Value

When the information processing apparatus 1 performs the pre-processing such as removal of the abnormal value such as the outlier or the missing value caused by the abnormal sensor in advance or interpolation from other time series data, it can be expected to improve the modeling accuracy.

### Data Cutout

When the information processing apparatus 1 cuts out and uses only the time series data in the periods necessary for the modeling, unnecessary dynamics or noise can be reduced, and it can be expected to improve the modeling accuracy.

### Decimation

The sampling period of the time series data has an appropriate value for improving the modeling accuracy in accordance with the time constant of the target system. The information processing apparatus 1 collects the time series data in a sampling period as short as possible, and performs the pre-processing of decimation in which the down-sampling and the low-pass filtering are performed later, so that the data can be processed with an appropriate sampling period. In the decimation processing, since there is a possibility that aliasing in which frequency components equal to or higher than the Nyquist frequency circulate in a low frequency band may occur due to the down-sampling, it is preferable to apply an anti-aliasing filter which is a low-pass filter having the Nyquist frequency as a cutoff frequency.

### <Summary>

In the information processing system according to the present embodiment configured as described above, the information processing apparatus 1 acquires the time series observed temperature data in which the temperature as the state of the substrate processing apparatus 3 is observed, and calculates the parameters of the model that predicts, based on the observation information at the first point in time, the observation information at the second point in time, by the dynamic mode decomposition based on the acquired observed data. The first and second observation information may be the observed data itself, or may be data obtained by performing some arithmetic processing on the observed data. By performing the dynamic mode decomposition based on the time series data relating to the substrate processing apparatus 3 to calculate the parameters, the information processing apparatus 1 can be expected to perform, for example, the determination of the presence or absence of the abnormality relating to the processing performed by the substrate processing apparatus 3 using the calculated parameters, and can be expected to effectively utilize the time series data obtained from the substrate processing apparatus 3.

In the information processing system according to the present embodiment, the information processing apparatus 1 acquires the time series control input data for the substrate processing apparatus 3, and calculates the parameters of the model that predicts the second observation information at the second point in time based on the first control information and the first observation information at the first point in time by the dynamic mode decomposition with control input based on the acquired control input data and observed temperature data. The control input information may be control input data itself, or may be data obtained by performing some arithmetic processing on the control input data. With this configuration, the information processing apparatus 1 can perform the dynamic mode decomposition using the control input data in addition to the observed temperature data to determine the presence or absence of the abnormality, and thus the information processing apparatus 1 can be expected to perform processing such as this determination with higher accuracy.

In the information processing system according to the present embodiment, the information processing apparatus 1 calculates the parameters of the model by the dynamic mode decomposition for each processing unit of the substrate processing apparatus 3, for example, each time one wafer is processed. The information processing apparatus 1 can be expected to determine the presence or absence of the abnormality by comparing the parameters calculated for each processing unit with, for example, the parameters relating to the normally processed wafer, the parameters relating to the wafer for which the abnormality has been detected, and the like.

In the information processing system according to the present embodiment, the information processing apparatus 1 acquires the internal state data (modes) of the substrate processing apparatus 3 and the matrix indicating the relationship between the observed temperature data and the internal state data by the dynamic mode decomposition. The information processing apparatus 1 can be expected to, for example, detect a difference relating to the internal state of the substrate processing apparatus 3 by comparing the past normal/abnormal mode and the current mode and estimate the cause of the abnormality relating to the current substrate processing. Further, the information processing apparatus 1 can be expected to detect a difference relating to an observation system such as sensors of the substrate processing apparatus 3 by comparing a past normal/abnormal relationship matrix and the current relationship matrix, for example, and estimate the cause of the abnormality or the like relating to the current substrate processing.

In the information processing system according to the present embodiment, the internal state data (modes) of the substrate processing apparatus 3 and the matrix indicating the relationship between the observed temperature data and the internal state data are displayed in a visualized manner on a graph, a heat map, or the like. In this way, the user can be expected to estimate the cause of the abnormality or the like relating to the substrate processing, based on the displayed graph or heat map. Further, based on the estimated cause of the abnormality, parameters of the substrate processing (the parameters may include temperature control, i.e., heating and/or cooling of the wafer, voltage parameters, or any other parameter(s) related to the substrate processing or wafer transfer may be changed to resolve the abnormality and additional substrate processing may be performed.

In the information processing system according to the present embodiment, data relating to the heating or cooling of the wafer processed by the substrate processing apparatus 3 is used as the control input data, and data relating to the temperature of the wafer measured by the sensor is used as the observed data. With this configuration, the information processing apparatus 1 can be expected to perform, for example, the determination of the abnormality relating to the temperature control of the substrate processing apparatus 3.

In the information processing system according to the present embodiment, data of control input to the movable part 3b of the substrate processing apparatus 3 is used as the control input data, and data relating to the position, the speed, or the acceleration of the movable part 3b measured by the sensor is used as the observed data. With this configuration, the information processing apparatus 1 can be expected to perform, for example, the determination of the abnormality relating to the control of the movable part 3b provided in the wafer transfer mechanism or the like of the substrate processing apparatus 3. The present invention can utilize a neural network that is a specialized hybrid system integrated into a substrate processing apparatus, such as a semiconductor wafer etching chamber or wafer transfer mechanism, to enable real-time adaptive control and anomaly detection with improved accuracy over traditional Dynamic Mode Decomposition (DMD)-based methods. The neural network is designed to address a specific technical challenge: the difficulty of accurately predicting and responding to complex, non-linear dynamics in substrate processing under real-world conditions like sensor noise, hardware variability, and irregular control inputs (e.g., pulsed laser signals as in Modification Example 2). Unlike a generic neural network that processes data abstractly, this system is embedded within the apparatus's control loop and leverages a novel architecture to enhance the physical operation of the machine.

In the present embodiment, the temperature control of the substrate processing apparatus 3 and the control of the movable part 3b have been described as examples, but the application of the present technology is not limited to the two controls, and can be applied to various types of control of the substrate processing apparatus 3.

The graphs, the heat maps, and the like illustrated in the present embodiment are merely examples, and are not limited thereto. Further, the information processing apparatus 1 may visualize and display various information obtained through the dynamic mode decomposition.

The embodiments disclosed herein are exemplary in all respects and can be considered to be not restrictive. The scope of the present disclosure is indicated by the claims, not the above-described meaning, and is intended to include all modifications within the meaning and scope equivalent to the claims.

The features described in each embodiment can be combined with each other. In addition, the independent and dependent claims set forth in the claims can be combined with each other in any and all combinations, regardless of the reciting format. Furthermore, the claims use a format of describing claims that recite two or more other claims (multi-claim format). However, the present disclosure is not limited thereto. The claims may also be described using a format of multi-claims reciting at least one multi-claim (multi-multi claims).

1. An information processing method executed by an information processing apparatus, the information processing method comprising:
acquiring time series observed data in which a state of a substrate processing apparatus is observed;
calculating parameters of a model that predicts, based on first observation information regarding the observed data at a first point in time, second observation information regarding the observed data at a second point in time after the first point in time, by dynamic mode decomposition based on the acquired time series observed data;
i. determining an abnormality in substrate processing based on the calculated parameters; and
correcting the abnormality,
or
ii. detecting a difference in the state of the substrate processing apparatus based on the calculated parameters; and
providing, by the information processing apparatus, the detected difference data for display on a graphical user interface (GUI).

2. The information processing method according to claim 1, further comprising acquiring time series control input data for the substrate processing apparatus; and
calculating the parameters of the model that predicts the second observation information based on first control information regarding the control input data at the first point in time and the first observation information by dynamic mode decomposition with control input based on the acquired time series control data and time series observed data.

3. The information processing method according to claim 1,
wherein the substrate processing apparatus includes a plurality of processing units,
the parameters of the model are calculated for each processing unit of the substrate processing apparatus, and
the method further comprises comparing the parameters of each processing unit to detect a difference in the state of the substrate processing apparatus between the processing units.

4. The information processing method according to claim 3,
wherein a plurality of modes relating to the state of the substrate processing apparatus are acquired by the dynamic mode decomposition, and
the modes for each processing unit are compared to detect a difference in the state of the substrate processing apparatus between the processing units.

5. The information processing method according to claim 4, further comprising:
acquiring relationship information of the plurality of modes and the observed data by the dynamic mode decomposition; and
comparing pieces of the relationship information of each processing unit to detect a difference in an observation system of the substrate processing apparatus between the processing units.

6. The information processing method according to claim 4, further comprising displaying a graph illustrating characteristics of the modes and a heat map illustrating a relationship between the modes and the observed data in a matrix form.

7. The information processing method according to claim 2,
wherein the control input data is data of control input relating to heating or cooling of a wafer to be processed by the substrate processing apparatus, and
the observed data is observed data relating to a temperature of the wafer.

8. The information processing method according to claim 2,
wherein the control input data is data of control input for a movable part of the substrate processing apparatus, and
the observed data is observed data relating to a position, a speed, or acceleration of the movable part.

9. A non-transitory computer-readable storage medium having computer-executable instructions stored thereon, which when executed by one or more processors, cause the one or more processors to perform a method comprising:
acquiring time series observed data in which a state of a substrate processing apparatus is observed;
calculating parameters of a model that predicts, based on first observation information regarding the observed data at a first point in time, second observation information regarding the observed data at a second point in time after the first point in time, by dynamic mode decomposition based on the acquired time series observed data;
i. determining an abnormality in substrate processing based on the calculated parameters; and
correcting the abnormality,
or
ii. detecting a difference in the state of the substrate processing apparatus based on the calculated parameters; and
providing, by the information processing apparatus, the detected difference data for display on a graphical user interface (GUI).

10. The non-transitory computer-readable storage medium according to claim 9, wherein the method further comprises:
acquiring time series control input data for the substrate processing apparatus; and
calculating the parameters of the model that predicts the second observation information based on first control information regarding the control input data at the first point in time and the first observation information by dynamic mode decomposition with control input based on the acquired time series control data and time series observed data.

11. The non-transitory computer-readable storage medium according to claim 9,
wherein the substrate processing apparatus includes a plurality of processing units,
the parameters of the model are calculated for each processing unit of the substrate processing apparatus, and
the method further comprises comparing the parameters of each processing unit to detect a difference in the state of the substrate processing apparatus between the processing units.

12. The non-transitory computer-readable storage medium according to claim 11,
wherein a plurality of modes relating to the state of the substrate processing apparatus are acquired by the dynamic mode decomposition, and
the modes for each processing unit are compared to detect a difference in the state of the substrate processing apparatus between the processing units.

13. The non-transitory computer-readable storage medium according to claim 12, wherein the method further comprises:
acquiring relationship information of the plurality of modes and the observed data by the dynamic mode decomposition; and
comparing pieces of the relationship information of each processing unit to detect a difference in an observation system of the substrate processing apparatus between the processing units.

14. The non-transitory computer-readable storage medium according to claim 12, wherein the method further comprises displaying a graph illustrating characteristics of the modes and a heat map illustrating a relationship between the modes and the observed data in a matrix form.

15. The non-transitory computer-readable storage medium according to claim 10,
wherein the control input data is data of control input relating to heating or cooling of a wafer to be processed by the substrate processing apparatus, and
the observed data is observed data relating to a temperature of the wafer.

16. The non-transitory computer-readable storage medium according to claim 10,
wherein the control input data is data of control input for a movable part of the substrate processing apparatus, and
the observed data is observed data relating to a position, a speed, or acceleration of the movable part.

17. An information processing apparatus comprising:
a controller having a processor and a memory with a computer readable program stored therein that upon execution of the computer readable program by the processor configures the controller to:
acquire time series observed data in which a state of a substrate processing apparatus is observed; and
calculate parameters of a model that predicts, based on first observation information regarding the observed data at a first point in time, second observation information regarding the observed data at a second point in time after the first point in time, by dynamic mode decomposition based on the acquired time series observed data;
i. determine an abnormality in substrate processing based on the calculated parameters; and
correct the abnormality,
or
ii. detect a difference in the state of the substrate processing apparatus based on the calculated parameters; and
provide, by the information processing apparatus, the detected difference data for display on a graphical user interface (GUI).

18. The information processing apparatus according to claim 17, wherein the processor is further configured to:
acquire time series control input data for the substrate processing apparatus; and
calculate the parameters of the model that predicts the second observation information based on first control information regarding the control input data at the first point in time and the first observation information by dynamic mode decomposition with control input based on the acquired time series control data and time series observed data.

19. The information processing apparatus according to claim 17,
wherein the substrate processing apparatus includes a plurality of processing units,
the parameters of the model are calculated for each processing unit of the substrate processing apparatus, and
wherein the controller is further configured to compare the parameters of each processing unit to detect a difference in the state of the substrate processing apparatus between the processing units.

20. The information processing apparatus according to claim 19,
wherein a plurality of modes relating to the state of the substrate processing apparatus are acquired by the dynamic mode decomposition, and
the modes for each processing unit are compared to detect a difference in the state of the substrate processing apparatus between the processing units.
